(19) United States
(12) Patent Application Publication
(10) Pub. No.: US 2006/0086605 A1
(43) Pub. Date: Apr. 27, 2006

(54) Method for magnetron sputtering

(76) Inventors: Guy Clavareau, Havelange (BE); Patrick Lefevre, Romedenne (BE)

Correspondence Address: STEINBERG & RASKIN, P.C., 1140 AVENUE OF THE AMERICAS, 15th FLOOR, NEW YORK, NY, 10036-5803, US

(21) Appl. No.: 10/532,007

(22) PCT Filed: Oct. 22, 2003
(86) PCT No.: PCT/BE03/00179

§ 371 Date: Apr. 20, 2005

(30) Foreign Application Priority Data
Oct. 23, 2002 (BE) 20020606

(51) Int. Cl. C23C 14/32; C23C 14/00

(52) U.S. Cl. 204/192.1; 204/192.13

(57) ABSTRACT

The invention relates to a method for enhancing erosion uniformity on the sputtering surface of a magnetron cathodic sputtering target. The invention is characterised in that it consists in adding to said target intended to be coupled to a magnetron maintained fixed as compared to this target, at least one ferromagnetic piece for complete or partial insertion into said target or by juxtaposition thereto, so as to bring about, at the entire sputtering surface, a curvature reduction of the magnetic induction lines generated by the magnetron.

The present invention relates to a method for enhancing erosion uniformity on the sputtering surface of a magnetron cathodic sputtering target.

The well-known method for coating a substrate with a thin pellicle of material consists in sputtering said material when a difference of potential of several hundred volts is applied between two plates within a chamber filled with a gas at a pressure of about 0.3 to 7 pascals.

The gas, generally a rare gas such as neon or krypton, usually argon, is ionised to this pressure under the action of an electric field and the positive ions so formed bombard the cathode causing the transport of material from the cathodic sputtering target to the anodic substrate.

A classical cathodic sputtering cathode is generally made of a polar basis plate, on the centre and circumference of which permanent magnets are placed, the central magnets being of reversed polarity in comparison with the one of the lateral magnets.

Moreover, a cooling plate is placed between the magnets and the target, the cooling being direct or indirect. On the other hand, given their sensitivity to heat, the magnets are cooled thanks to a water circuit.

The so placed magnets create a magnetic induction which, once coupled to the existing electric field, allows the increasing of the electron pathway so as to locate the plasma on the level of the target. This confinement is important because it allows the increasing of the deposit speed during the cathodic sputtering of the target and it is maximum when the electric field and the magnetic induction are perpendicular, that is to say when the magnetic induction is parallel to the target.

However, given the shape of the magnetic induction caused by the magnets and its lack of uniformity, the space where this magnetic induction is parallel to the target is very limited and the density of the produced plasma is not uniform, leading to different sputtering rates on the target surface as well as to a typical V-shaped and race-track shaped wearing. In the best instance, only 30% of the target can be used.

In order to enhance the sputtering rate, it is thus necessary to modify the distribution of the magnetic induction so as to enhance the erosion uniformity of the target.

Different solutions have been proposed, most of them consisting in modifying the fixed cathodic assembly.

As an example, it is described in U.S. Pat. No. 4,198,283 a magnetron cathodic assembly including among others a sputtering target which has been modified by the addition of polar pieces fixed to the target support plate, these polar pieces being intended to emphasize the curvature of the magnetic field in the shape of a closed loop above the target surface.

Likewise, British Patent, GB 2209769, describes a sputtering system which means for inducing a magnetic field include a magnetic material extending in the direction of the anode beyond the surface supporting the target on its side situated distant from the anode. This polar material is separated from the circular target by means of an aluminium ring.

In addition, an article extracted from the “38^{th} Annual Technical Conference Proceeding”, page 414, discloses a method for increasing the performance of plane targets, intended to magnetron sputtering, by the use of a linking ferromagnetic piece placed between the magnet assembly and the target so as to favourably modify the magnetic field on the level of said target surface.

Moreover, Patent Application EP 1 063 679, describes a method for reducing the excessive local erosion of a sputtering target used with a mobile magnetron as compared to this target. According to this method, one or several polar pieces are introduced between the magnet assembly and the target as well as in the places where picks of erosion are observed, these pieces being able to act on the magnetic field and, as a consequence, able to bring about a reduction of the excessive local erosion without influencing the rest of the erosion process on the target.

Likewise, Patent Application JP 03271366 explains how to place a ferromagnetic piece in the erosion ring of a sputtering target either by complete or partial insertion in said target or by juxtaposition thereto so as to control the plasma produced thanks to an external magnetic field induced by a solenoid.

On the other hand, Patent Application EP 0 393 957 discloses the use of a ferromagnetic piece embedded in a groove on the level of the back wall of a sputtering target so as to reinforce the central wall of the target support which is also embedded in said groove as well as to reinforce the target against any radial expansion caused by heat.

All the above-mentioned methods require the addition of modifications which sometimes can be very important as regard to the fixed sputtering means represented by the magnetron, in particular the fixed cathodic assembly. Given that these modifications have to take into account not only the magnetron characteristics but also the properties of the target used, any change of these properties could render useless these modifications and could eliminate all the advantages researched with respect to the target erosion.

The objective of the present invention is to offer a method for erosion uniformity on the entire sputtering surface of a sputtering target and for overcoming the inconveniences of the state of the art and more particularly for avoiding modifying the fixed assembly of the magnetron.

To achieve this objective, the method for enhancing erosion uniformity on the sputtering surface of a magnetron cathodic sputtering target is characterised in that it consists in adding to said target, intended to be coupled to a magnetron maintained in a fixed position as compared to this target, at least one ferromagnetic piece by complete or partial insertion into said target or by juxtaposition thereto, so as to bring about, at the entire sputtering surface, a curvature reduction of the magnetic induction lines generated by the magnetron.

Further to the fitting of a sufficient number of ferromagnetic pieces having adequate characteristics of position, shape and size, a reduction of the magnetic induction lines curvature is observed which often leads to a parallelism increase of said lines with respect to the target surface so as to reach a significantly important increase of the rate of parallel magnetic induction lines. This evolution to a more important parallelism of the magnetic induction lines can be noticed at the entire sputtering surface.

As a consequence, according to a preferred embodiment of the invention, at least one ferromagnetic piece is added either by complete or partial insertion into said target or by juxtaposition thereto, so as to bring about, at the entire sputtering surface, a curvature reduction of the induction lines generated by the magnetron which leads to a parallelism increase of said induction lines.

According to another particularly preferred embodiment, the ferromagnetic piece(s) are completely or partially inserted into the target.

Said ferromagnetic piece, belonging to the method according to the invention, is made of a material permeable to the magnetic field such as steel, soft iron or a soft magnetic alloy (“PERMALLOY®”), for example an iron-nickel alloy optionally including another metal such as molybdene.

It can be, depending on the case, completely or partially inserted into the target in place of an extracted portion of said target. In any event, this extracted portion is totally replaced by the corresponding portion of a ferromagnetic piece.

In other cases, this polar piece can be juxtaposed to the target, that is to say placed against one of its walls which is usually in direct contact with the wall opposed to the sputtering surface.

When the target is made of a low melting point material such as zinc, the ferromagnetic piece(s) will be inserted or juxtaposed, preferably and as far as possible, to the ends of this target or to its lower face, that is to say the face opposed to the sputtering surface, in order to maintain an efficient cooling of said target and avoid its liquefaction.

As a consequence, according to another embodiment of the invention, when the target is made of a low melting point material, the ferromagnetic piece(s) are inserted from the ends of the target or from its lower face or juxtaposed to the ends of the target or to its lower face.

On the other hand, the ferromagnetic piece, when it is inserted into the target, may also be an indicator of the end of use of this target once its erosion has reached said ferromagnetic piece.

As a consequence, according to another of its aspects, the invention relates to a method for enhancing erosion uniformity on the sputtering surface of a magnetron cathodic sputtering target as well as for indicating the end of use of said target, wherein at least one ferromagnetic piece is added to said target designed to be coupled to a magnetron maintained in a fixed position as compared to said target either by complete or partial insertion into said target or by juxtaposition thereto, so as to bring about, at the entire sputtering surface a reduction of the curvature of the magnetic induction lines generated by the magnetron which particularly leads to a parallelism increase of said induction lines.

As for the target, which is usually plate, it can be of different shapes such as circular or rectangular and be endowed or not with round angles.

According to another embodiment of the invention, at least one ferromagnetic piece is added which characteristics of location, shape and size are predetermined from the magnetron physical characteristics.

Moreover, according to another preferred embodiment of the invention, at least one ferromagnetic piece is added which characteristics of location, shape and size are predetermined from the magnetron physical characteristics, by:
a) comparing the measured values and the modelled values of the total magnetic induction generated by the magnetron on the target sputtering surface on the one hand and of the vertical component of said magnetic induction on the other hand,
b) searching in this modelled induction the characteristics of location, shape and size of at least one ferromagnetic piece able to bring about, at said sputtering surface, the desired curvature reduction of the magnetic induction lines which particularly leads to the desired parallelism increase of said induction lines,
c) optimizing, by means of the

$$\frac{B z}{{B}_{total}}$$
parameter, the selected location, shape and size characteristics.

Likewise, according to another particularly preferred embodiment of the invention, at least one ferromagnetic piece is added which characteristics of location, shape and size are predetermined from the magnetron physical characteristics, by:
a) measuring the values of the total magnetic induction generated by the magnetron and of the vertical component of this magnetic induction,
b) modelling, by means of a software-assisted computer technique, the total magnetic induction and its vertical component,
c) comparing the modelled values of the total magnetic induction on the one hand and of its vertical component on the other hand with the corresponding measured values,
d) searching in this modelled induction, the characteristics of location, shape and size of at least one ferromagnetic piece able to bring about, at the level of the target sputtering surface, the desired curvature reduction of the magnetic induction lines which particularly leads to the desired parallelism increase of said induction lines,
e) optimizing, by means of the

$$\frac{B z}{{B}_{total}}$$
parameter, the selected position, shape and size.

As a consequence, the insertion or juxtaposition of at least one ferromagnetic piece is carried out after the predetermination not only of the location but also of the shape and size of said piece.

Generally and preferably, this predetermination of location, shape and size is carried out thanks to a bidimensional or tridimensional modelling of the magnetic induction which is obtained by means of an adequate software-assisted computer technique.

This modelling allows the visualisation of the magnetic induction geometry, the magnetic induction itself and the magnetic induction lines previously calculated. This modelling is then validated by comparing the calculated values for the magnetic induction with the corresponding measured values.

Moreover the modelling of the vertical component of the modelled induction is also validated by comparing the calculated values for said vertical component with the measured corresponding values.

In a further step, a virtual ferromagnetic piece is inserted into the modelled magnetic induction and the desired modification of the magnetic induction is searched by translation of said modelled induction in order to increase the curvature of the magnetic induction lines at the level of the sputtering surface of the virtual target integrated in the modelling, or in another way, in order to decrease the value of the vertical magnetic induction component, i.e. Bz.

Given that the addition of this ferromagnetic piece decreases the total magnetic induction, i.e. Bₜₒₜₐₗ, represented by the square root of (Bx²+By²+Bz²) at the place of insertion into the target or juxtaposition thereto, it is possible to optimise the location, shape and size of this piece in the modelled induction.

Since a parallelism increase of the magnetic induction lines above the target sputtering surface is preferably searched, the main goal of this optimisation is to select the magnetic induction area(s) where the value of the parameter

$$\frac{B z}{{B}_{total}}$$

is the lowest while keeping a sufficient magnetic induction for a sufficient confinement of the electrons at the target sputtering surface, usually an induction equal to at least 100 gauss.

When this parameter is equal to zero, the magnetic induction lines are perfectly parallel to the target and, if it is equal to one, those lines are quite vertical.

It is then necessary to find on the real sputtering target the optimised position for the settlement of the real ferromagnetic piece which shape and size are so defined and to proceed to the insertion or juxtaposition of said piece.

This insertion is usually carried out according to known techniques after extraction, by cutting up, of the necessary portion of the target and consists in replacing said portion by an equivalent portion of a ferromagnetic piece which shape has been obtained especially by manufacture.

As regard to the juxtaposition of the ferromagnetic piece to the sputtering target, it is generally carried out according to a known method, for example by sticking.

The method, according to the invention, designed to magnetron cathodic sputtering presents incontestable advantages with respect to the state of the art. Indeed, the realisation of this method allows the increasing of the uniformity of the sputtering target wearing, which leads to a significant broadening of the erosion area as well as to an attendant reduction of the V-shaped erosion path. As a consequence, given that it is possible to reach an erosion rate of about 70%, the use of the target can be considerably enhanced.

Moreover, the application of this method also has the advantage to avoid any modification of the magnetron but to act only at the level of the target which is a removable element easy to reach on a magnetron.

The invention will be better understood and other goals, characteristics and advantages will appear clearly through the following explicative description made in conjunction with the attached drawings given as examples illustrating embodiments of the present invention and wherein:

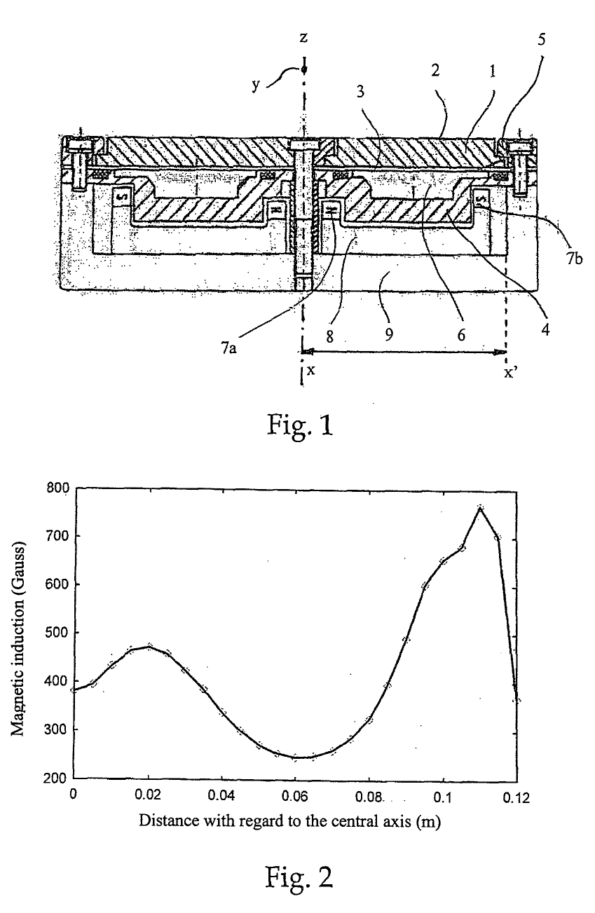

FIG. 1 is a schematic representation of a frontal cut of a sputtering magnetron cathode endowed with a sputtering target

FIG. 2 is a bidimensional graphic representation of the total magnetic induction measured at the fitting surface of the sputtering target

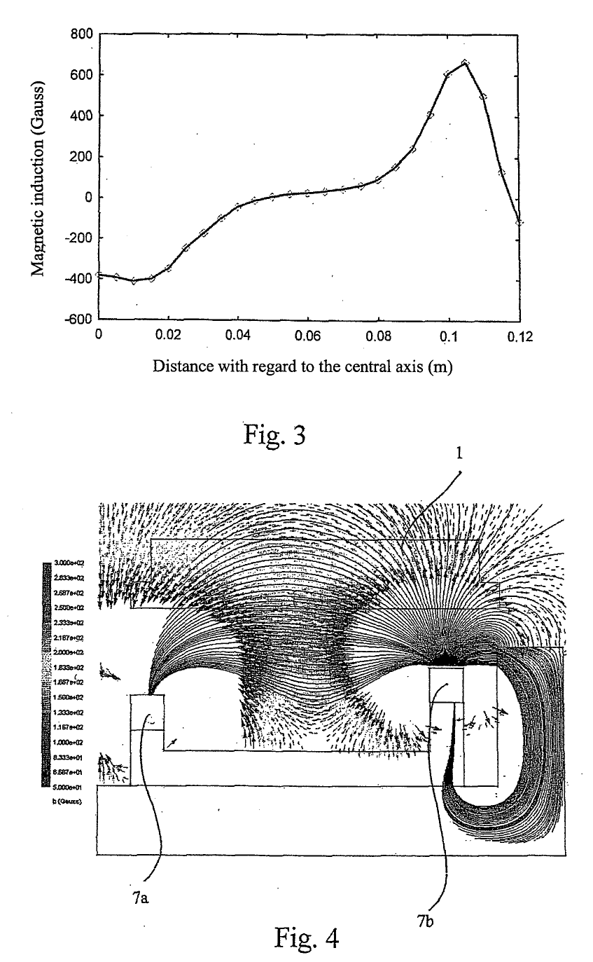

FIG. 3 is a bidimensional graphic representation of the measure of the magnetic induction vertical component illustrated in FIG. 2

FIG. 4 is a bidimensional representation of a modelling of the magnetic induction above the sputtering surface of the target illustrated in FIG. 1

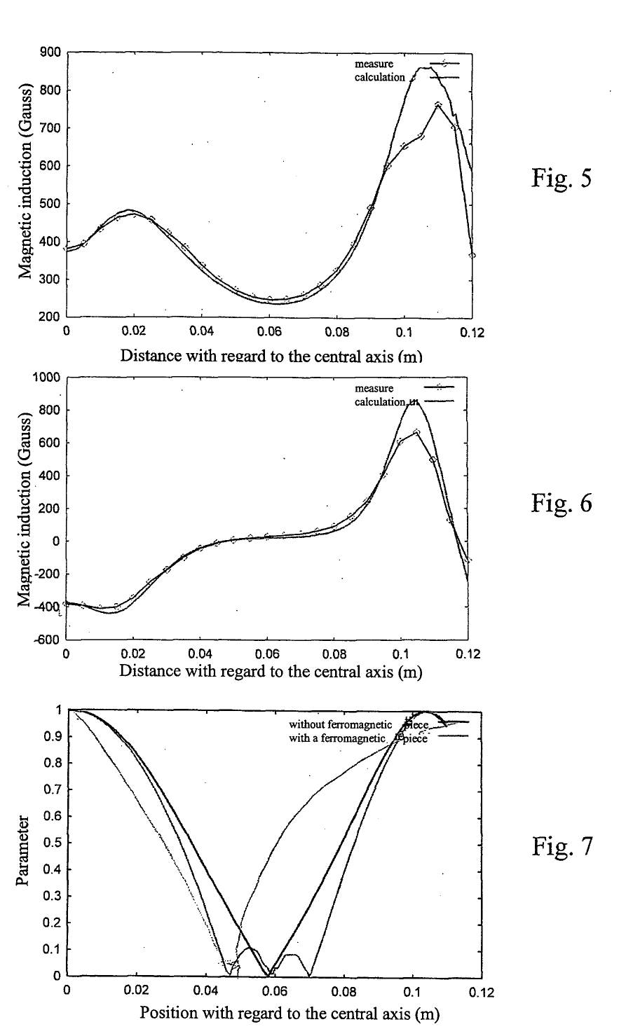

FIG. 5 is a comparative bidimensional graphic representation of the measure of the total magnetic induction illustrated in FIG. 2 and of the calculation of said total magnetic induction

FIG. 6 is a comparative bidimensional graphic representation of the measure of the magnetic induction vertical component illustrated in FIG. 3 and of the calculation of said magnetic vertical component

FIG. 7 is a graphic representation of the quotient

$$\frac{B z}{{B}_{total}}$$

for the magnetic induction calculated at the target sputtering surface

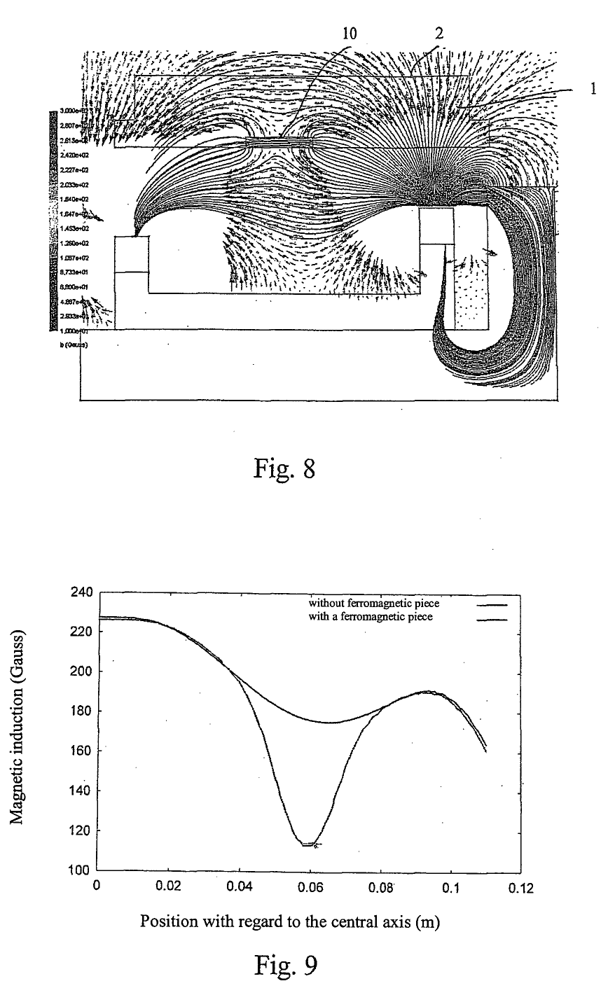

FIG. 8 is a bidimensional graphic representation of the modelling illustrated in FIG. 3 including a ferromagnetic piece

FIG. 9 is a comparative bidimensional graphic representation of the total magnetic induction calculated at the level of the target sputtering surface with or without ferromagnetic piece

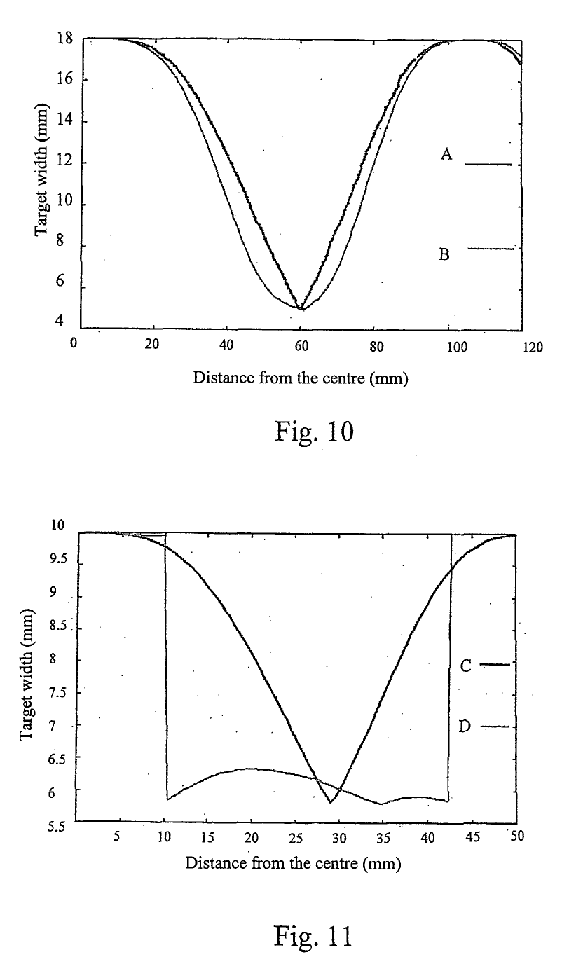

FIGS. 10 to 11 are comparative bidimensional graphic representations of a computer simulation of the target erosion with or without ferromagnetic piece.

### EXAMPLE 1

On a magnetron endowed with a sputtering cathodic assembly, schematically illustrated in FIG. 1, a target 1 has been illustrated which sputtering surface is represented in 2. This target is fixed to a copper plate 3 forming support and maintained on a cooler 4 by means of a clamp 5 whereas a bowl 6 dug from the upper part of the cooler 4 contains a liquid, usually water, intended for the cooling of said plate 2.

The physical characteristics of the magnetron are researched and to this effect, the position of the permanent magnets 7a and 7b and of the cathode ferromagnetic pieces 8 and 9 are located, then the total magnetic induction Bₜₒₜₐₗ is measured in a conventional way by means of an adequate measuring device. For reasons of accessability, said measure is carried out at the level of the fitting surface of the target 1 on the cooling plate 3. This is carried out from the vertical central axis z, or vertical symmetry axis, of this cathode on a segment of a line X-X′ perpendicular to the axis z and to the longitudinal central axis y, or longitudinal symmetry axis, as well as at different places of said segment, 120 mm length.

The measure of the magnetic induction vertical component, Bz, is carried out in an analogous way.

FIGS. 2 and 3 represent the magnetic induction curvatures so measured for Bₜₒₜₐₗ and Bz, respectively.

From the physical characteristics of the magnetron and with the help of an adequate computer software, Bₜₒₜₐₗ and Bz are calculated thanks to a finite element method and a bidimensional computer modelling of the calculated magnetic induction is carried out as illustrated in FIG. 4.

This figure shows the modelled geometry of the magnetic induction, the magnetic induction represented by arrows and the magnetic induction lines calculated as well as the position of the virtual target 1 with respect to the virtual magnets 7a and 7b.

A comparison between the curve representing calculated Bₜₒₜₐₗ and the curve representing measured Bₜₒₜₐₗ, illustrated in FIG. 2, allows the validation of the proposed modelling in FIG. 5.

An analogous comparison carried out between the curve representing calculated Bz and the curve representing measured Bz, such as illustrated in FIG. 3, allows the same conclusion as illustrated in FIG. 6.

In a further step, a virtual ferromagnetic piece is introduced into the modelled magnetic induction so as to bring about a modification of said magnetic induction distribution in order to increase, in the present case, the curvature of the induction lines at the entire sputtering surface 2 of the virtual target 1 or, in another way, to decrease the Bz value.

FIG. 7 illustrates, by way of a graphic, a comparison between the values of this parameter, in absence or presence of a ferromagnetic piece, obtained along the considered right segment X-X′ at the target sputtering surface.

In the absence of ferromagnetic piece integrated to the target, it can be noted that

$$\frac{B z}{{B}_{total}} = 0$$

at a distance of 58 cm from the cathode central axis z. At this place, Bz is zero and the magnetic induction lines are parallel to the target surface.

However, the integration of a ferromagnetic piece with adequate shape and size, at a determined place of the magnetic induction allows the cancelling of this parameter at distances of 46 mm and 69 mm from the axis z and, as a consequence, the parallelism increase of the induction lines with respect to this target.

The modelling of the magnetic induction field modified by means of the above-mentioned ferromagnetic piece 10 perfectly shows, in FIG. 8, the parallelism increase of the induction lines at the target 1 sputtering surface 2 as compared to the induction lines at the same place of the target exempt of ferromagnetic piece such as represented in FIG. 4.

In addition, as shown and confirmed in FIG. 9, the chosen position, for integration of a ferromagnetic piece can be retained given that the magnetic induction remains higher than 100 gaus.

To such a place of sputtering target 1, a portion of this target is cut and extracted, portion which ends are located at 38 mm and 58 mm from axis z, respectively and the extracted volume is replaced by an equivalent volume of a ferromagnetic piece which external surface is brought to the same level than the fitting surface of target 1 on cooling plate 3. manufactured indicates in FIG. 10 a significant broadening of the erosion area illustrated by curve B as compared to the erosion illustrated by curve A recorded with an identical target exempt of inserted or juxtaposed ferromagnetic piece.

In the above-mentioned example, the ferromagnetic piece 10 is inserted in the lower part of the target. However, there exist other possibilities which depend among others on the properties of the material from which the target is made and of the working facilities.

### EXAMPLE 2

As explained in Example 1, a mounting has been built which includes a sputtering target and a ferromagnetic piece inserted thereto, the mounting being configured so as to reduce the magnetic induction curvature and increase the parallelism of the magnetic induction lines at the target sputtering surface.

A simulation by computer technique of the erosion after cathodic sputtering of the target being part of the mounting so built indicates in FIG. 11, an extremely important broadening of the erosion area illustrated by curve D as compared to the erosion area illustrated by curve C, recorded with an identical target exempt of any inserted or juxtaposed ferromagnetic piece.

1. (canceled)

2. (canceled)

3. (canceled)

4. (canceled)

5. (canceled)

6. (canceled)

7. (canceled)

8. (canceled)

9. Method for enhancing erosion uniformity on the sputtering surface of a magnetron cathodic sputtering non-ferromagnetic target and, optionally, for indicating the end of use of this target, intended to be coupled, via non-magnetic means, to a magnetron maintained fixed as compared to this target, wherein it is possible, without modifying the physical characteristics of the magnetron, at least one ferromagnetic piece is added by partial or complete insertion into said target or by juxtaposition thereto according to predetermined characteristics of location, shape and size, so as to bring about, at the entire sputtering surface, an increase of the parallelism of the magnetic induction lines generated by the magnetron.

10. Method according to claim 9, wherein the characteristics of location, shape and size of the ferromagnetic piece are predetermined, from unmodified physical characteristics of the magnetron, by
a) comparing the measured values and the modelled values of the total magnetic induction, I.e. Bₜₒₜₐₗ, generated by the magnetron on the target sputtering surface and of the vertical˜component, i.e. B_{z}, of said magnetic induction,
b) searching in this modelized induction the characteristics of location, shape and size of at least one ferromagnetic piece able to bring about, at the sputtering surface, the desired increase of the parallelism of the magnetic induction lines,
c) optimizing, by means of the |B_{z}|/Bₜₒₜₐₗ parameter the selected location, shape and size.

11. Method according to claim 9, wherein the characteristics of location, shape and size of the ferromagnetic piece are predetermined, from unmodified physical characteristics of the magnetron, by:
a. measuring the values of the total magnetic induction, i. e. Bₜₒₜₐₗ generated by the magnetron at the target sputtering surface and of the vertical component, i.e. B_{z}, of this magnetic induction,
b. calculating and modelling, by means of a software-assisted computer technique, the total magnetic induction generated by the magnetron at the target sputtering surface and of the vertical component of this magnetic induction,
c. validating the modelling by comparing the calculated values of the total magnetic induction of the one hand and of its vertical component on the other hand with the corresponding measured values,
d. searching in this modelled induction the characteristics of location, shape and size of at least one ferromagnetic piece which, once in contact with the sputtering target, is able to bring about, at the target sputtering surface, the desired increase of the parallelism of the magnetic induction lines,
e. optimizing, by means of the B_{z}/Bₜₒₜₐₗ parameter, the selected position, shape and size.

12. Method according to claim 10, wherein the characteristics of location, shape and size are optimized via the selection of the magnetic induction area(s) where the value of the B_{z}/Bₜₒₜₐₗ parameter is as low as possible, the magnetic induction remaining sufficient in order to bring about an efficient confinement of the electrons at the target sputtering surface.

13. Method according to claim 9, wherein at least one ferromagnetic piece is added by partial or complete insertion in the sputtering target.

14. Method according to claim 9, wherein at least one ferromagnetic piece is added by juxtaposition on one wall of the sputtering target.

15. Method according to claim 9, wherein, when the target is made of a low melting point material, at least one ferromagnetic piece is added by insertion either from the ends of the sputtering target or from its lower face or by juxtaposition either against the walls of this target ends or against the lower face wall of this target.
